(19) United States
(12) Patent Application Publication
(10) Pub. No.: US 2025/0274091 A1
(43) Pub. Date: Aug. 28, 2025

(54) Circuit Architectures Addressing Erroneous Common-Mode Voltage

(71) Applicant: Elevation Microsystems, Inc., Wilmington, DE (US)

(72) Inventors: Celal Avci, Istanbul (TR); Ferhat Ozturk, Istanbul (TR); Batuhan Dogan, Istanbul (TR); Emrah Peker, Istanbul (TR); Emre Topcu, Istanbul (TR)

(21) Appl. No.: 19/063,281

(22) Filed: Feb. 25, 2025

Related U.S. Application Data
(60) Provisional application No. 63/557,700, filed on Feb. 26, 2024.
(60) Provisional application No. 63/558,245, filed on Feb. 27, 2024.

(51) Int. Cl. H03F 3/45; H03F 1/34

(52) U.S. Cl. CPC H03F 3/45932; H03F 1/342; H03F 3/45475

(57) ABSTRACT

In one embodiment, an electrical circuit can include one or both of two different circuit architectures that provide robust protection against spurious common-mode signals, including common-mode degradation and transient common-mode signals. When used in electrical isolators, these circuit architectures improve common-mode signal quality over the isolation barrier and maintain signal quality by reducing common-mode degradation.

### PRIORITY CLAIM

This application claims the benefit under 35 U.S.C. § 119 of (1) U.S. Provisional Patent Application No. 63/557,700 filed Feb. 26, 2024 and (2) U.S. Provisional Patent Application No. 63/558,245 filed Feb. 27, 2024, which are incorporated by reference herein.

### TECHNICAL FIELD

This application generally relates to circuit architectures that address erroneous common-mode voltage.

### BACKGROUND

A common-mode signal is a voltage component that is present at different inputs of an electrical component. Common-mode voltages are present in many circuits, such as electrical isolators, which create electrical separation between two or more components of an electrical system. However, electrical isolators can pass signals or power through the isolated components, for example by using capacitive or inductive methods. For instance, electrical isolators may be used to safely transmit data between electrical components that operate at different voltage domains.

### BRIEF DESCRIPTION OF THE DRAWINGS

FIG. 1 illustrates an example common-mode correction circuit in the context of a demodulator circuit.

FIG. 2 illustrates an example common-mode rejection circuit in the context of a demodulator circuit.

FIG. 3 illustrates an example common-mode rejection circuit.

FIG. 4 illustrates an example demodulator circuit that includes multiple common-mode rejection circuits.

### DESCRIPTION OF EXAMPLE EMBODIMENTS

Electrical isolators, such as isolated gate drivers and digital isolators, are widely used to maintain safe signal transmission between different voltage domains, including in electrical vehicles, solar inverters, industrial automation, and in communication circuits. Common mode transient immunity is an important characteristic of an electrical isolator, as common-mode transients can occur due to voltage spikes between the different domains.

Electrical isolators may include a modulator, an isolation barrier, and a demodulator. Common-mode transients and other degradations of a common-mode signal degrades communication over the isolation barrier and within the circuitry of an isolator, such as within the modulator and demodulator circuitry. While an isolation barrier can limit some common-mode transient signals from passing over the barrier, some transient signals (e.g., relatively large and fast common-mode transients) nevertheless pass over the barrier.

In addition, common-mode disturbances in a circuit can arise from components within that circuit (e.g., within a demodulator circuit). For instance, there is often a mismatch between components in a differential amplifier in a circuit, where the positive input is connected to a gate of one MOSFET in the amplifier, while the negative input is connected to a gate of the other MOSFET. If there is a mismatch between this MOSFET-MOSFET pair, then even a perfect differential signal will result in the amplifier output some common signal, and this common signal will be amplified by other stages and/or may degrade detector capabilities (e.g., due to detector's limited voltage range).

As another example, common-mode noise may degrade a common voltage. As another example, parasitic effects can create common-mode degradation—e.g., each differential pair of MOSFETS has a load and if one MOSFET's conductive routing is longer than the other, then that longer path will have more resistance, and common-mode degradation will result. Finally, differential amplifiers are designed to amplify only a differential signal. But in practice such amplifiers are not perfect, and therefore some common-mode signal is amplified and erroneously introduced to downstream components in the circuit.

This disclosure describes two distinct (and in particular embodiments, complementary) circuit architectures that provide robust protection against spurious common-mode signals, including common-mode degradation and transient common-mode signals. When used in electrical isolators, these circuit architectures improve common-mode signal quality over the isolation barrier and maintain signal quality by reducing common-mode degradation. As explained herein, example implementations of these circuit architectures include isolated electrical systems, such as isolated gate drivers, digital isolators, and isolated ADCs, etc.

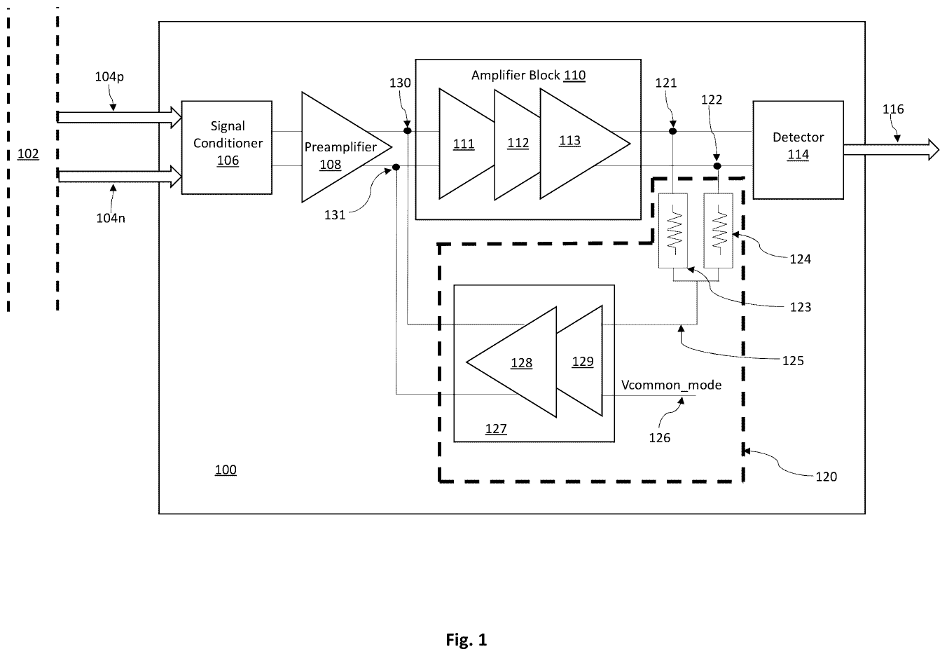

FIG. 1 illustrates an example common-mode correction circuit 120 in the context of a demodulator circuit 100. In the example of FIG. 1, demodulator circuit 100 is separated by an isolation barrier 102 from a modulator (not shown). In the example of FIG. 1, a demodulator positive input 104p and a demodulator negative input 104n are input to demodulator circuit 100. In general, this disclosure uses the convention that the upper line is positive while the lower line is negative, although this disclosure contemplates that either the upper input line or the lower input line could be at voltages that are relatively more positive than the other.

Demodulator circuit 100 includes a signal conditioner stage 106 to condition the input signal 104p and 104n. The conditioned signal is passed to preamplifier 108. The output of preamplifier 108 is the input to amplifier block 110, which contains one or more amplifiers. The example of FIG. 1 illustrates three amplifiers 111, 112, and 113, although more or fewer amplifiers may be used in an amplifier block. Amplifiers 111, 112, and 113 in amplifier block 110 are connected in serial. The output of amplifier block 110 is the input to detector 114, which outputs a demodulated signal 116.

Common-mode correction circuit 120 detects the common-mode voltage at its inputs 121 and 122. Common-mode correction circuit 120 compares the detected common-mode voltage and compares that with the common-mode voltage V_{cm} used for demodulator circuit 100, which is provided by input 126 to amplifier block 127 of the common-mode correction circuit 120. The common-mode voltage detected by common-mode correction circuit 120 is provided to input 125 of amplifier block 127.

Common-mode correction circuit 120 in the example of Fig. I uses two resistors 123 and 124 to detect the common-mode voltage, although this disclosure contemplates that any suitable circuitry may be used instead of, or in addition to, resistors 123 and 124. The resistor values typically have the same value that will typically be in the megaohm range, although other values may be used depending on the parameters and requirements of amplifier block 110 and the detector input. The example common-mode correction circuit 120 of FIG. 1 includes two amplifiers 128 and 129 in amplifier block 127, although this disclosure contemplates that more or fewer amplifiers may be used in an amplifier block of a common-mode correction circuit.

After comparing the detected common-mode voltage with the common-mode voltage V_{cm} used by the demodulator circuit, amplifier block 127 amplifies the difference between those two voltages and provides a negative feedback loop to demodulator circuit 100, via outputs 130 and 131, to correct the common mode voltage in demodulator circuit 100.

The example of FIG. 1 illustrates common-mode correction circuit 120 as (1) having its input connected to the output of amplifier block 110 of demodulator 100 and (2) having its output connected to the input of amplifier block 110. However, this disclosure contemplates that a common-mode correction circuit may be connected at other locations; for example, the output of common-mode correction circuit 120 may be connected to the input of preamplifier 108, or may be connected to the output of one of the intermediary amplifiers within an amplifier chain (e.g., may be connected to the output of amplifier 111 or 112).

Typically, the most appropriate place to put a common-mode correction circuit described herein is where the common-mode voltage is most degraded. For instance, each amplifier stage typically introduces some common-mode degradation, and therefore the location of common-mode correction circuit 120 in the example of FIG. 1 has its inputs where the common mode is most degraded (i.e., after amplifier block 110). Another factor in where to place a common-mode correction circuit is that the output of the common-mode correction circuit will introduce some parasitic load to the circuit it connects to. In the example of FIG. 1, the output of preamplifier 108 has low impedance, and therefore the effect of additional parasitic loading due to common-mode correction circuit 120 will be relatively low, making the output of preamplifier 108 an ideal location to connect the output terminals 130 and 131 of common-mode correction circuit 120. The considerations discussed above will generally apply to other circuits, and the output of an amplifier block will typically be a good place to connect the input of a common-mode correction circuit, and the input of the amplifier block will typically be good place to connect the output of the common-mode correction circuit, but this disclosure contemplates that a common-mode correction circuit may have other connection locations. For instance, a common-mode correction circuit may correct the common-mode voltage of a particular amplifier in an amplifier chain, and multiple common-mode correction circuits may be used, each corresponding to a particular amplifier.

While the example circuit of FIG. 1 includes a single common-mode correction circuit 120, other embodiments may introduce multiple common-mode correction circuits, each having at least a different output location in the circuit. For instance, a demodulator circuit may contain multiple common-mode correction circuits, each having its input connected to the input of a detector circuit, and each having its output connected to a different input of an amplifier in an amplifier block. In particular embodiment, there may be n amplifiers and n common-mode correction circuits, each having an output connected to a different one of the amplifier inputs.

While the example of FIG. 1 illustrates a common-mode correction circuit in the context of a demodulator circuit, the common-mode correction circuit techniques described herein may be used in any other type of circuit. As explained above, a demodulation circuit can particularly benefit from a common-mode correction circuit, as the demodulation input signal will be relatively low, and accurately detecting this low signal is a significant challenge, so high amplification is used to generate a detectable signals. However, this high amplification also results in relatively high common-mode degradation. Other circuits that require relatively high amplification of input signals may likewise particularly benefit from more common-mode correction circuits.

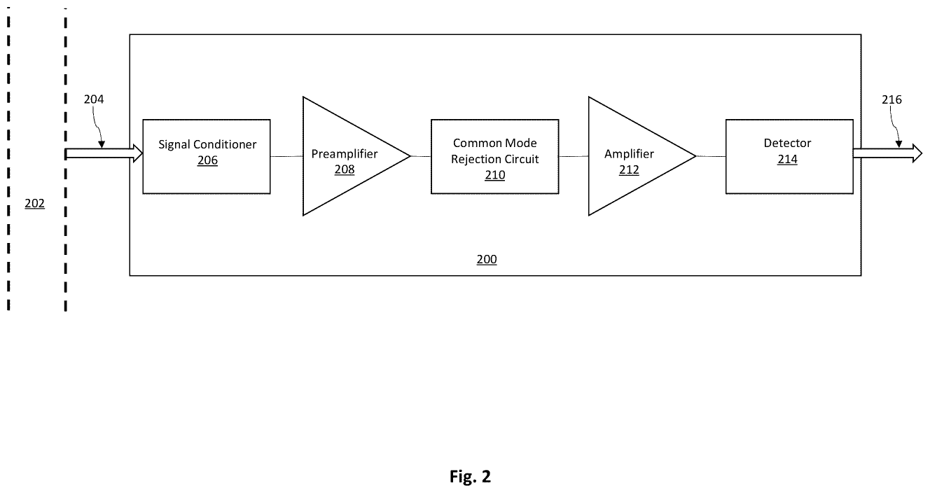

FIG. 2 illustrates an example of a common-mode rejection circuit 210. As explained below, a common-mode rejection circuit as described herein rejects the input common-mode signal and, in particular embodiments, resets the common-mode signal to a desired level.

The example of FIG. 2 illustrates common-mode rejection circuit 210 in the context of a demodulator 200. Demodulator 200 receives an input signal 204 from a modulator (not shown), which is separated from demodulator 200 by isolation barrier 202. In the example of FIG. 2, demodulator 200 includes signal conditioner stage 206, preamplifier 208, common-mode rejection circuit 210, amplifier 212, and detector 214, which outputs demodulator 200's output signal 216.

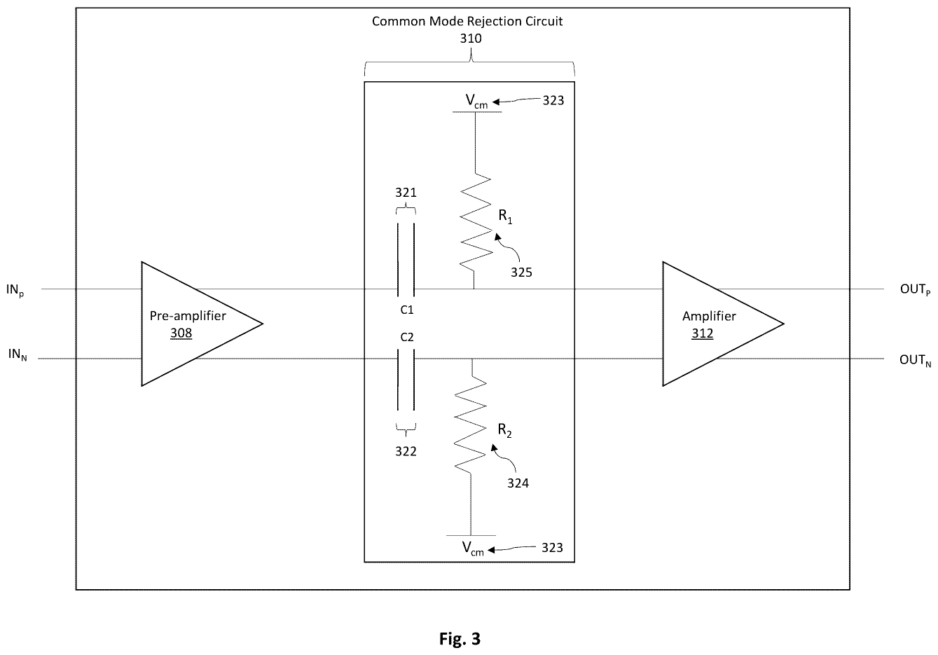

FIG. 3 illustrates an example common-mode rejection circuit 310, which receives input from preamplifier 308 and provides output to amplifier 312. In the example of FIG. 3, common-mode rejection circuit 310 includes two capacitors, 321 and 322, each of which sits in series with the output of preamplifier 308. For instance, capacitor 321 may be in series with the positive output of preamplifier 308, while capacitor 322 may be series with the negative output of the preamplifier. The value of capacitors 321 and 322 are typically set to be the same value, but may differ in particular embodiment. In practice, the precise capacitor values used will depend on the circuit's design and characteristics of its input signal, as the capacitors will reject some of the desired input signal, and so the ideal balance between rejected common-mode signal vs. rejected desired signal will vary from circuit to circuit.

Capacitors 321 and 322 are also in series with the input of amplifier 312. Capacitors 321 and 322 therefore operate as, and are examples of, high-pass filters that pass the demodulation signal while blocking the low-frequency (e.g., DC) common-mode signal. Thus, the common-mode signal in the output of preamplifier 308 is rejected from the input to amplifier 312, achieving high common mode transient immunity and reducing or eliminating the effects of common-mode degradation.

In particular embodiments, such as in the example of FIG. 3, rejecting the common- mode voltage in the output of one circuit element (e.g., preamplifier 308) results in an undefined common voltage at the input of a downstream circuit element (e.g., amplifier 312), which can result in erroneous circuit operation. Therefore, particular embodiments reset a desired common voltage level after rejecting the input common voltage. The example common-mode rejection circuit 310 includes resistors 323 and 324 that are in parallel with capacitors 321 and 322 and the respective input lines of amplifier 312. Resistors 323 and 324 are in series between those respective input lines and a desired common-mode voltage V_{cm}, thereby re-introducing the desired common-mode voltage to amplifier 312. The value of resistors 323 and 324 will typically be the same, and will typically be relatively high so as to prevent parasitic loading.

As a result, common-mode degradation that would otherwise occur at the input of amplifier 312 is rejected by capacitors 321 and 322, and a clean, desired common-mode V_{cm} is introduced at that input. In addition, the common mode V_{cm} introduced by common-mode rejection circuit 310 may be different than the common-mode voltage rejected by that circuit, thereby adapting the common-mode voltage to the ideal value for input to amplifier 312. For instance, in general the desired common-mode voltage V_{cm} may be the common-mode voltage that is used for the entire circuit, or may be the desired common-mode voltage specifically for amplifier 312.

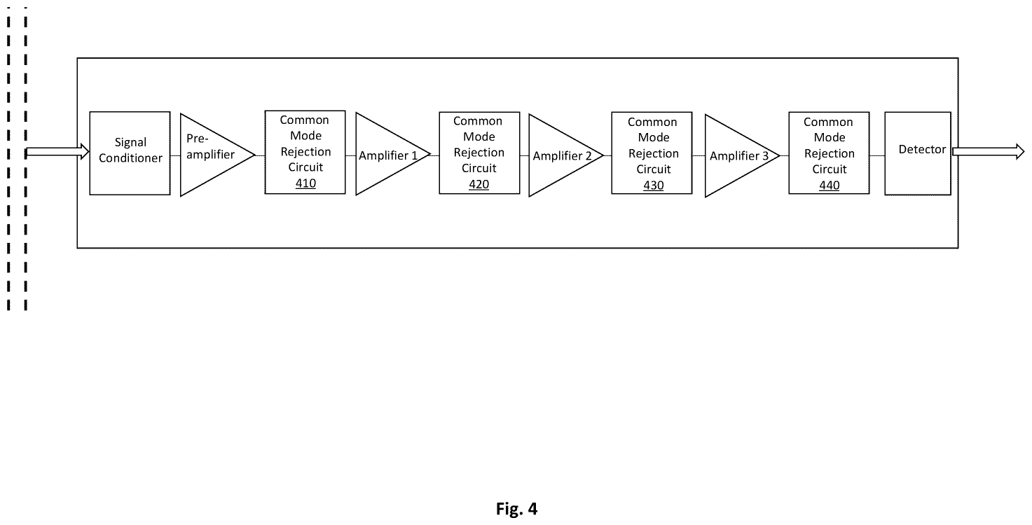

The example of FIGS. 2-3 illustrates a signal amplifier 312, but this disclosure contemplates that multiple amplifiers may be used in an amplifier block. In particular embodiment, multiple common-mode rejection circuits may be used in a circuit, as well. FIG. 4 illustrates an example demodulator circuit that includes multiple common-mode rejection circuits. In the example of FIG. 4, each common-mode rejection circuit serves a particular circuit component by (1) rejecting the common-mode voltage input to that component and (2) setting the common-mode voltage for that component. Here common-mode rejection circuit 410 serves amplifier 1, common- mode rejection circuit 420 serves amplifier 2, common-mode rejection circuit 430 serves amplifier 3, and common-mode rejection circuit 440 serves the detector. In the example of FIG. 4, the capacitive and/or resistor values may vary among the common-mode rejection circuits. In addition, each common-mode rejection circuit may set a different V_{cm}, depending on the needs of the component it serves. Thus, each common-mode rejection circuit can reject the degraded common- mode voltage input to its respective downstream component and then set a common-mode voltage specifically for that downstream component. Each amplifier stage is therefore decoupled from the others, allowing each stage to be optimized (e.g., stage gain and available input and output swings) independently. Thus, each amplifier stage's common-mode voltage is separately controllable without disturbing the common-mode voltage levels of any other stage. This enables independent design and optimization of each amplifier stage for best performance such as gain, power consumption and area.

In particular embodiments, a circuit may include one or more common-mode rejection circuits to reject (and, in particular embodiments, to set) common-mode voltages and one or more common-mode correction circuits to correct common-mode voltages. For instance, in the example of FIG. 4, a common-mode correction circuit may be introduced to the circuit, and that common-mode correction circuit may have its inputs connected to the input of the detector and its output connected to the output of the preamplifier. Other embodiments may use more than one common-mode correction circuit; for instance, a common-mode correction circuit may be added for each common-mode rejection circuit, such that the common-mode correction circuit's input is the output of a particular amplifier and the common-mode correction circuit's output is the input of that amplifier. Other embodiments may use other configurations for a circuit that includes both a common-mode correction circuit and a common-mode rejection circuit.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend.

What is claimed is:

1. A common-mode correction circuit comprising:
input circuitry configured to detect a common-mode voltage of a first circuit; and
a negative feedback loop circuit configured to:
amplify a difference between (1) the detected common-mode voltage of the first circuit and (2) a correct common-mode voltage; and
output the amplified difference to the first circuit.

2. The common-mode correction circuit of claim 1, wherein the first circuit comprises a demodulator circuit.

3. The common-mode correction circuit of claim 2, wherein demodulator circuit comprises a preamplifier, a detector, and an amplifier block comprising one or more amplifiers coupled between, and in series with, the preamplifier and the detector.

4. The common-mode correction circuit of claim 3, wherein:
the input circuitry is coupled to an input of the detector; and
the output of the negative feedback loop circuit is coupled to an output of the preamplifier.

5. The common-mode correction circuit of claim 3, wherein the input circuitry comprises a pair of resistors, each resistor coupled to a differential output of the amplifier block.

6. The common-mode correction circuit of claim 3, wherein the negative feedback loop circuit comprises an amplifier block comprising one or more amplifiers.

7. A circuit comprising at least one common-mode rejection circuit, the common-mode rejection circuit comprising:
a first high-pass filter coupled in series with a first input to the common-mode rejection circuit;
a second high-pass filter coupled in series with a second input to the common-mode rejection circuit;
a first resistor coupled (1) in series between a correct common-mode voltage V_{cm} and a first output of the common-mode rejection circuit and (2) in parallel with the first capacitor and the first output; and
a second resistor coupled (1) in series between the correct common-mode voltage V_{cm} and a second output of the common-mod rejection circuit and (2) in parallel with the second capacitor and the second output.

8. The circuit of claim 7, further comprising a demodulator circuit.

9. The circuit of claim 7, wherein the common-mode rejection circuit is coupled between a preamplifier and an amplifier chain comprising one or more amplifiers.

10. The circuit of claim 9, further comprising one or more additional common-mode rejection circuits, each additional common-mode rejection circuit coupled between a pair of amplifiers in the amplifier chain.

11. The circuit of claim 10, further comprising a terminal common-mode rejection circuit coupled between a terminal amplifier in the amplifier chain and a detector.

12. The circuit of claim 10, wherein at least two of the common-mode rejection circuits set a different correct common-mode voltage.
